(19) United States
(12) Patent Application Publication
(10) Pub. No.: US 2024/0365518 A1
(43) Pub. Date: Oct. 31, 2024

(54) COOLING CONTROL OF ELECTRONIC DEVICES UTILIZING PORT STATUS LIGHTS

(71) Applicant: HEWLETT PACKARD ENTERPRISE DEVELOPMENT LP, Spring, TX (US)

(72) Inventor: Michael Robert Frith, Rancho Cordova, CA (US)

(21) Appl. No.: 18/306,383

(22) Filed: Apr. 25, 2023

(51) Int. Cl. H05K 7/20

(52) U.S. Cl. CPC H05K 7/20836; H05K 7/20736; H04L 12/10

(57) ABSTRACT

A networking device may comprise ports connectable via respective communications links to remote devices. Each of the ports is associated with at least one port status light that is configured to indicate a status of the port. The networking device may also comprise one or more fans, which are configured to provide an airflow through the networking device. The networking device may additionally comprise control circuitry. The control circuitry may, in a state of at least one remote device being connected to at least one of the ports, be configured to monitor drive signals for driving the port status lights and control the airflows provided by the one or more fans based at least in part on the drive signals for driving the port status lights.

### INTRODUCTION

Networking devices, such as switches, routers, or access points, generally have ports into which communication cables can be removably connected to allow for data to be communicated through the networking device (e.g., between two client devices coupled to respective ports of the networking device). Examples of such ports include RJ45 ports, which may be connected to Ethernet cables. In particular, some networking devices may be capable of providing power-over-ethernet (PoE) on one or more of their ports, which allows for data signals and electrical power supply signals to be communicated over the same, single ethernet cable. This may allow a PoE-enabled electronic device to be communicably coupled to a network and to receive power via the same cable, which may provide more flexibility in how the device can be deployed (e.g., the device may no longer need to be positioned near a power outlet or have long power cables to reach such an outlet). In a PoE system, a device that provides the power to other devices via PoE is referred to as a Power Sourcing Equipment (PSE) and the devices that receive power from the PSE are referred to as Powered Devices (PD). The PSE generally also serves as a networking element, such as a switch or router. PDs may also be networking elements (e.g., a wireless access point, a PoE repeater/hub, etc.), network end points (e.g., a security camera, an internet-of-things (IoT) device, etc.), or any other electronic device with a PoE port.

Port Status lights, e.g., port status LEDs, are commonly provided adjacent to ports of the networking device, for example, adjacent to one or more PoE ports of the electronic device, and are driven to indicate a status of a respective port. For example, the status LED of a port may be turned on when a connection is active or off when no connection is active. Or, in a PoE networking device, a port status LED may be turned on when PoE power is being supplied via the port and off otherwise. In other examples, the port status LED may be driven based on an amount of data traffic passing through the port, for example the LED may flash at a rate that depends on the amount of traffic. In addition, in some systems, different colors may be used to indicate different things. Furthermore, in some systems, the port status LEDs may be configurable by a user to indicate one of multiple statuses.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example networking device.

FIG. 2 is a block diagram illustrating a first example fan control logic.

FIG. 3 is a block diagram illustrating a second example fan control logic.

FIG. 4 is a block diagram illustrating an example storage medium storing instructions executable by a processor of a networking device.

FIG. 5 is a process flow chart illustrating a first example method performable by a networking device.

FIG. 6 is a process flow chart illustrating a second example method performable by a networking device.

FIG. 7 is a process flow chart illustrating a third example method performable by a networking device.

FIG. 8 is a process flow chart illustrating a fourth example method performable by a networking device.

### DETAILED DESCRIPTION

Electronic devices, such as, for example, networking devices generate heat while powered up and in use. Consequently, networking devices may be provided with one or more fans that are configured to flow air over the components of the networking device to dissipate the heat generated by the networking device and to cool its components. Thus, there is generally a correlation between the heat generated and the airflow required, such that as more heat is generated, more airflow is needed to appropriately cool the components, and more airflow is provided by increasing the rotational speed of the fans. However, there is also generally a correlation between fan speed and noise output, such that the greater the fan speed, the more noise the fans generate, and in some cases the noise can become excessive and irritate users. Thus, driving the fans at full speed to ensure adequate cooling may not be a satisfactory solution in all circumstances. Instead, it is generally desired to maintain the fans at a speed that is just high enough to dissipate the amount of heat currently being generated by the device, so that high fan speeds (and the consequent noise) only occur when actually necessary (i.e., when the device is generating a lot of heat). It is thereby desirable to drive the fans at moderate or low fan speeds, or to be able to turn the fans off entirely, when possible, to reduce the noise.

It may be difficult sometimes, however, to know how much heat is being generated by the device at any given time, thereby making it also difficult to determine the optimal fan speed to control the fans appropriately. One approach to controlling the fans is to provide temperature sensors in the networking device and to control the fan speed based on one or more functions that relate the sensed temperatures to the fan speeds. Such functions are generally referred to as a “fan curve,” “speed curve,” or “fan speed curve.” But using temperature sensors and fan curves to control device cooling (e.g., fan speeds) may not always be feasible or yield satisfactory results. In particular, not all networking devices are equipped with temperature sensors, in which case the use of temperature-based fan curves is not possible. Moreover, other networking devices are equipped with a limited number of temperature sensors, such that the networking device has sensors in certain portions of the device and not in others, thereby limiting the functionality and accuracy of the sensors as different portions of the networking device may have materially different cooling needs depending on the circumstances.

For example, in some networking devices, a power supply unit (PSU) that supplies power to the rest of the networking device may be separated from the main electronic control circuitry (e.g., CPU, switching hardware, etc.) of the networking device. This separation may result from baffles or other structures that define separate internal compartments into which the electronic control circuitry and the PSU are disposed, or the electronic control circuitry and the PSU may be separated in the sense of being disposed distant from one another (even if not being physically cordoned off). In some such examples, the temperature sensors may be provided in or adjacent to the main electronic control circuitry but may not be provided near the PSU. Thus, in such systems, the speed of the fan(s) may be controlled primarily based on the temperature of the control circuitry, whereas the temperature of the PSU may have less influence (or no influence at all) on the fan speed. If a single fan is provided to cool both PSU and control circuitry, then the PSU may be inadequately cooled in circumstances in which the PSU is at a high temperature, but the electronic control circuitry is at a low temperature, since the speed of the single fan is controlled based primarily (if not solely) on the temperature of the electronic control circuitry. This circumstance of a high temperature PSU and a lower temperature control circuitry can occur in any device but is particular likely to happen in PoE networking devices, as the PSU may need to supply power to multiple PDs (and thus the PSU may be at a high temperature) even if the PDs are not currently generating a lot of data traffic (and thus the control circuitry is at a lower temperature (i.e., the temperature controlled area or the temperature monitored area is at a lower temperature)). If separate fans are provided for the PSU and the electronic control circuitry, then there may be no way to control the PSU fan based on the temperature of the PSU because there are no temperature sensors near the PSU, and thus the PSU fan may need to either be driven at full speed all the time (which generates excessive noise) or the PSU fan may need to be controlled based on the temperature sensors of the electronic control circuitry, which results in similar difficulties as noted above with respect to using a single fan. While an obvious solution to the above problems would be to provide temperature sensors for the PSU, this is not always feasible. In particular, in some cases, providing a temperature sensor for the PSU may be cost prohibitive, as it may require a redesign of a system board layout, which can be quite costly.

To address these and other issues, examples disclosed herein provide for controlling the rotational speed of the fan(s) of a networking device based on port status light driving signals. For convenience, the description below will refer to port status LEDs, but it should be understood that any types of lights could be used as the port status lights, including but not limited to LEDs, and the descriptions herein related to port status LEDs and their associated driving signals are also applicable to any other type of port status light. These port status LED driving signals are generated by an LED control logic to control the port status LEDs, and in examples provided herein a fan control logic may monitor these port status LED driving signals and use them to control the fan speed. The port status LEDs can serve as a proxy for the temperature of components of the networking device because the port status LEDs may indicate information about the degree to which various components of the networking device are loaded, and the temperature of these components will tend to increase as their load increases. For example, in a PoE device, the temperature of the PSU may be dependent on the number of PDs that are drawing PoE power, and this may be indicated by the port status LED driving signals. In particular, the port status LEDs may be driven to turn ON when PoE power is being drawn from their respective ports, and thus the number of port status LED driving signals that have an ON-value may be counted to determine the number of PDs that are currently drawing PoE power, and this number may be used as a proxy for the temperature of the PSU in a fan control scheme. Moreover, in some systems the port status LEDs may indicate a load on components other than the PSU or a general load on the networking device as a whole, for example by indicating the number of client devices connected to the networking device, by indicating the amount of data traffic being transferred, or by indicating some other status of the ports that can be related to the load on the networking device.

In some examples, the fan speed may be controlled by directly setting a fan speed set point based on the port status LED signals. For example, in some circumstances the fan speed set point may depend on the number of port status LED signals that have a particular value (e.g., an ON value that causes the LED to emit light), with higher fan speed set points being used as the number of ON LEDs increases. As another example, in some circumstances, the status LEDs may indicate an amount of traffic passing through the port by flashing at a frequency or duty cycle (e.g., faster flashing or higher duty cycle indicates more traffic), and the fan speed set point may be controlled based on an aggregation of these signals. As yet another example, in some circumstances, the status LEDs may indicate when a port has an ON value, is in use, and/or has an increased load (i.e., connected at a known data rate that requires a known increase or decrease in power dissipation) by changing colors, and the fan speed set point may be controlled based on a combination of these signals.

In other examples, the fan speeds may be controlled based on a temperature-based fan curve (or some other fan control algorithm), and in such cases the fan speed may be indirectly controlled based on port status LED signals by changing the control that is used by the device. For example, in some implementations, a temperature-based fan curve that is used to control the fan speed may be changed between multiple different fan curves depending on the port status LED signals, with more aggressive fan curves being used when more port status LED signals have the ON value, or when the port status LED signals are otherwise indicating an increased load on the components (e.g., by flashing faster, changing colors, etc.).

In this manner, the device cooling control (e.g., fan control) described herein can be implemented without using temperature sensors (i.e., the electronic device does not need temperature sensors), thus allowing for intelligent fan control even in networking devices that lack such sensors. Moreover, the fan control described herein can also be integrated into networking devices that have temperature sensors to further improve the cooling performance of the systems. As discussed above, such systems may have a limited number of temperature sensors that do not adequately cover and reflect the cooling needs of the various components of the system, and the LED port status cooling control described herein may be implemented to control the cooling of the components that are not adequately covered by the temperature sensors. For example, if temperature sensors are present for the electronic control circuitry but not for the PSU, and if separate fans are provided for each, then the fan that cools the electronic control circuitry may be controlled based on the temperature sensors and the fan that cools the PSU may be controlled, at least in part, based on the port status LEDs (either directly, or indirectly). Or, as another example, if a single fan is provided for both PSU and electronic control circuitry (or multiple fans are provided but are all driven at the same speed as one another), then a temperature-based fan curve may be used to control the fans based on the temperature sensors but the fan curve may be adjusted based on the port status LED driving signals, as described above.

The port status LEDs and the associated logic to produce the driving signals for the LEDs are generally already present in most networking devices. Thus, the fan control described herein can make use of the information that is already present in these signals without having to provide additional sensors in the device and without needing to modify or have access to the lower-level hardware, firmware, or system software that controls the networking device. Thus, the solutions described herein can be relatively inexpensive to add to existing or future networking device designs.

Turning now to the figures, various devices, systems, and methods in accordance with aspects of the present disclosure will be described.

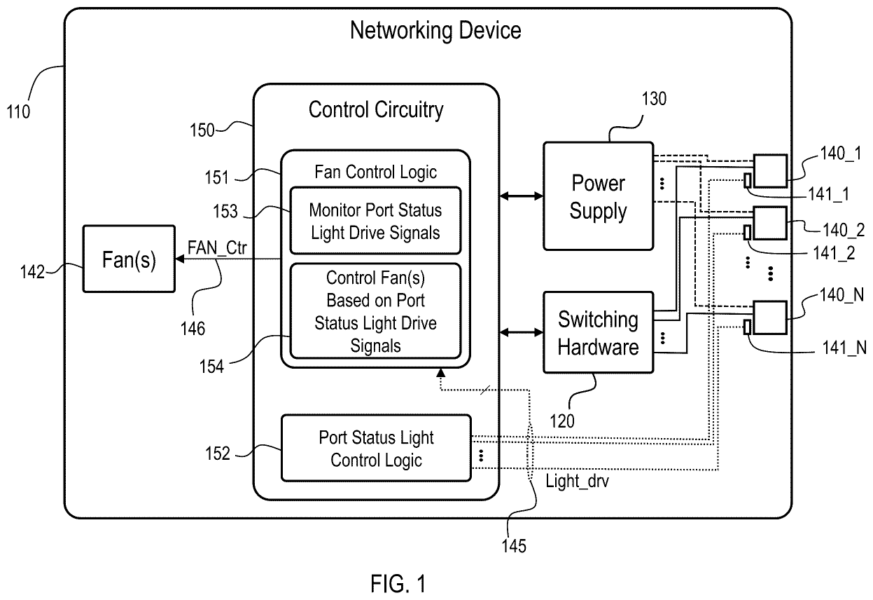

FIG. 1 is a block diagram conceptually illustrating an example networking device, in the form of a networking device 110. The networking device 110 may, for example, be a switch, a router, an access point, or any other networking device as would be understood by those of ordinary skill in the art. In various implementations, the networking device 110 may be a PoE networking device (e.g., the networking device 110 may have one or more PoE ports through which PoE power can be provided to a connected device), while in other implementations the networking device 110 may be a non-PoE device. Those of ordinary skill would understand that the networking device illustrated in FIG. 1 and described below is an example only and that FIG. 1 is therefore not intended to illustrate specific shapes, dimensions, or other structural details accurately or to scale, and that implementations of the networking device 110 may have different numbers and arrangements of the illustrated components and may also include other parts that are not illustrated.

As shown in FIG. 1, the networking device 110 comprises switching hardware 120, a power supply 130, a plurality of ports 140 (three ports 140_1, 140_2, 140_N being shown in FIG. 1, collectively referred to as “ports 140”), control circuitry 150, and one or more fans 142 that are configured to provide an airflow through the networking device 110, for example, to cool one or more components of the networking device 110.

The switching hardware 120 comprises switching circuitry that can selectively connect the ports 140 to one another and to one or more other ports, for example, ports of one or more remote devices (not illustrated), such as an uplink port to allow routing of data packets between the various remote devices connected to the networking device 110, as well as other related components that participate in, control, or otherwise facilitate the communication of the data packets between the networking device 110 and the one or more remote devices. Switching hardware of a networking device, such as, for example, a PSE is familiar to those of ordinary skill in the art, and thus the switching hardware 120 is not described in greater detail herein.

The power supply 130 provides electrical power to the networking device 110. As discussed above, in some examples, the networking device 110 is configured as a PoE power sourcing equipment (PSE), in which case the power supply 130 provides power not only to run the functions of the networking device 110 itself but also to supply PoE power to connected PDs via the ports 140. In examples in which the networking device 110 is configured as a PoE PSE, the power supply 130 may be controlled by the control circuitry 150 to selectively supply the PoE power to the ports 140, or in other words the power supply 130 can cease supplying PoE power to certain ports 140 under the direction of the control circuitry 150 if needed (for example, during a PSE power fault). The power supply 130 comprises one or more power supply devices that are configured to receive input power from a source, such as mains power or a power distribution unit, and convert that power into forms suitable for use by the networking device 110. The power supply devices of the power supply 130 may include an AC-to-DC converter, a DC-to-DC converter, protection devices (e.g., over-current protection, over-voltage protection, etc.), and/or other power components that participate in, control, or otherwise facilitate the supply of power to the networking device 110. Power supplies of a networking device, such as, for example, a PSE are familiar to those of ordinary skill in the art, and thus the power supply 130 is not described in greater detail herein.

The ports 140 may comprise any type of data communication port. For example, the ports 140 may comprise RJ45 jacks configured to receive complimentary RJ45 connectors of an Ethernet cable to enable communication using one of the Ethernet family of protocols. As another example, the ports 140 may comprise optical transceivers for receiving optical cables and communicating using light signals. Various other types of communications ports are familiar to those in the art and thus are not described in detail herein. The ports 140 are not necessarily all identical to one another, and in some examples different types of ports 140 may be used together within the same networking device 110. Each port 140 is coupled to the control circuitry 150 (e.g., via the switching hardware 120) and is configured to communicate data between the control circuitry 150 and a remote device (e.g., a PD) connected to the port 140. In examples in which the networking device 110 is a PoE PSE, at least some of the ports 140 may comprise PoE capable ports, and each of the PoE capable ports 140 is also coupled to the power supply 130 and configured to supply PoE power from the power supply 130 to the PD coupled to port 140 (unless PoE power has been disabled for the port 140 by the control circuitry 150). In FIG. 1 three ports (i.e., ports 140_1, 140_2, 140_N) are shown, but any number of ports 140 equal to or greater than two may be included in the networking device 110. Communication ports, including PoE ports, are familiar to those of ordinary skill in the art, and thus the ports 140 are not described in greater detail herein.

As further illustrated in FIG. 1, each port 140 has a respective port status light 141 associated with the port 140, which is configured to indicate a status of the port 140. In FIG. 1, in which three ports 140_1, 140_2, 140_N are shown, each port 140_1, 1402, 140_N has a respective port status light 141_1, 1412, 141_N associated with the port (collectively described herein as “port status lights 141”). In one implementation, the port status lights comprise light-emitting diodes (LEDs). The port status lights 141 are selectively turned on (i.e., caused to emit light) and/or illumination characteristics thereof are selectively changed to indicate a status and/or a status change of an associated port 140. In various examples, the illumination characteristics that can be changed to indicate various different statuses may include any combination of one or more of: the color of emitted light, the intensity of emitted light, whether the light is emitted in a steady or flashing manner, and a frequency of flashing. For example, the port status lights 141 may be configured to light up (i.e., provide a steady light indicator) to indicate a successful connection between the port 140 and a remote device, to flash (e.g., slow, fast and/or flickering to provide a blinking light indicator) to indicate transmission and/or receipt of data by the port 140 at a given rate, and/or change color to indicate a successful connection, an exchange of information, and/or one or more other port condition changes. Moreover, an individual port status light 141 (and in some examples, each port status light 141) may itself comprise multiple light emitting elements (e.g., multiple LEDs) which collectively form a port status indicator associated with a single port 140, such that each light of the port status light 141 may have a different color and/or meaning. For example, multiple light emitting elements (e.g., LEDs) may share the same window through which light is emitted and/or be positioned adjacent to one another, and thus these light emitting elements may appear to a user as if they were a single light source.

As used herein, “port status light” includes any type of lighted port activity and status indicator that is associated with a respective port, including but not limited to port status LEDs. “Port status LED” refers to a port status light in which one or more of the light emitting elements thereof is a light emitting diode (LED). Furthermore, “port status light” refers to a unit that can comprise multiple discrete light emitting portions that all emit light through a common “window.” Thus, as would be understood by those of ordinary skill in the art, in cases in which a port status light comprises multiple discrete light emitting portions (e.g., different colored light emitting diodes), multiple drive signals may be associated with the port status light (e.g., each port status light might receive a different drive signal for each one of its discrete colors). Those of ordinary skill in the art would also understand that depending on the configuration of a given networking device 110 (which may vary from one manufacturer to the next and/or from one device to the next), the contemplated port status lights 141 can have various lighted activity indicators, configured to run through various states, which have various meanings, and which can be positioned at various locations with respect to an associated port 140 (e.g., a window for a respective light unit can be positioned at various locations with respect to an associated port).

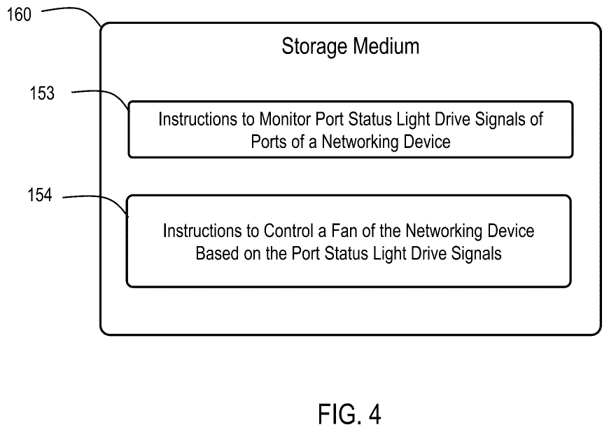

The control circuitry 150 comprises circuitry configured (e.g., programmed) to perform various operations that control the networking device 110. Among other things, the control circuitry 150 comprises fan control logic 151 to control the one or more fans 142 and port status light control logic 152 to control the port status lights 141 (e.g., the port status LEDs 141). As used herein, “logic” refers to dedicated hardware, software instructions stored in memory and coupled with a processor capable of executing the instructions, or some combination of these operations. The control circuitry 150, for example, comprises a processor (not shown) and a storage medium (see FIG. 4) storing instructions executable by the processor to cause various operations executed by the fan control logic 151 and the port status light control logic 152 to be performed, dedicated hardware configured to perform the operations, or some combination of these. In examples in which the control circuitry 150 comprises a processor, the processor may comprise one or more processing devices capable of executing machine readable instructions, such as, for example, a processor, a central processing unit (CPU), a controller, a microcontroller, a system-on-chip (SoC), a digital signal processor (DSP), a graphics processing unit (GPU), or other processing resources. In examples in which the control circuitry 150 includes dedicated hardware, in addition to or in lieu of the processor, the dedicated hardware may include any electronic device that is configured to perform specific operations, such as an Application Specific Integrated Circuit (ASIC), a Field Programmable Gate Array (FPGA), a Complex Programmable Logic Device (CPLD), discrete logic circuits, an analog circuit, a mixed control circuit, a hardware accelerator, a hardware encoder, etc. For example, in some implementations, some or all of the fan control logic 151 may be instantiated as an analog discrete logic circuit. For example, such a circuit may comprise comparators that may compare the analog status light drive signals (individually or summed) to predetermined voltage values and output one or more analog signals indicative of how many of the status light drive signals have a predetermined value (e.g., a high voltage value associated with an ON state for the lights). In addition, amplifiers, adders, and/or other analog logic devices may be included in the circuit as needed.

In some examples, as will be described further below, the fan control logic 151 is configured to execute an operation 153 to monitor drive signals 145 for driving the port status lights 141 (hereinafter “status light drive signals 145”). In some examples, the status light drive signals 145 may be generated by the port status light control logic 152, as discrete drive signals, as will be described in greater detail below. In some other examples, the status light drive signals 145 are embedded within a data stream containing other control or status signals. This embedded status light drive information can, for example, correlate to the same port activities and status indicators as those utilized by the discrete status light drive signals (e.g., an ON/OFF state, intensity, utilization, PoE link, link activity, data rate, etc.). In such examples, as would be understood by those of ordinary skill, the device(s) (e.g., external logic) that is used to process/decode the embedded data stream and push the data (i.e., the status light drive signals 145) to the port status lights 141 could also be configured to provide the decoded status light drive signals 145 to the fan control logic 151. Thus, as used herein, “status light drive signal” is intended to include both discrete and embedded status light drive signals.

The fan control logic 151 is further configured to perform an operation 154 to control the airflows provided by the one or more fans 142 based at least in part on the status light drive signals 145, via fan control signals 146. In this manner, in some examples the control circuitry 150 may comprise a storage medium 160 storing instructions executable by the processor (not shown) to cause operations 153 and 154 to be performed (as illustrated in FIG. 4), in other examples the control circuitry 150 may comprise dedicated hardware configured to perform operations 153 and 154, and in other examples control circuitry 150 comprises some combination of these.

As would be understood by those of ordinary skill in the art, the contemplated fan control logic 151 may comprise various control logics, which are configured to execute various operations to issue fan control signals 146, wherein the fan control signals 146 control aspects of operation of the fan(s) 142 including at least controlling the rotational speeds thereof. For example, the fan control logic 151 may determine set points for the rotational speeds of the fan(s) 142 and generate the fan control signals 146 such that they instruct or otherwise cause the fan(s) 142 to rotate according to the determined set points. The fan control signals 146 may be, for example, pulse-width-modulation (PWM) signals. As would be familiar to those of ordinary skill in the art, a PWM signal comprises a signal with repeating pulses wherein a duty cycle (pulse width) of the pulses is controlled so as to convey information, such as a fan speed set point in the case of fan control signals 146. Thus, the fan control logic 151 may determine a duty cycle for the fan control signals 146 that corresponds to the desired fan speed set point, and when the fan(s) 142 receive these fan control signals 146 they set their rotational speed according to the duty cycle thereof. Thus, in some examples the operation 154 described above of controlling the fan(s) 142 based at least in part on the status light drive signals 145 may comprise setting the fan speed set point, and hence the duty cycle of the fan control signals 146, based at least in part on the status light drive signals 145.

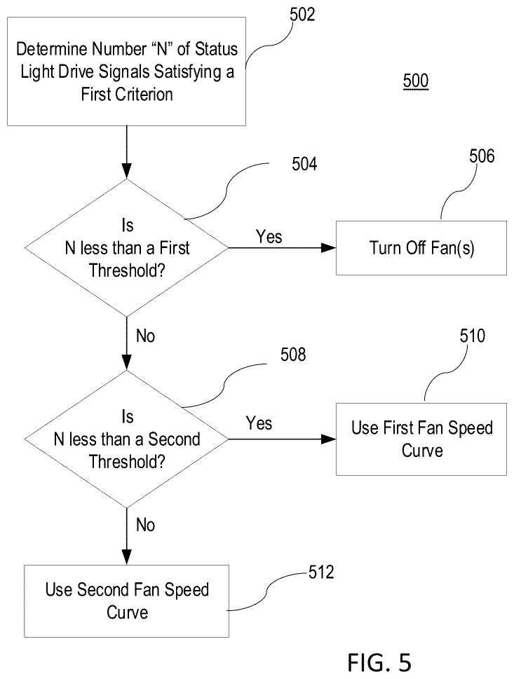

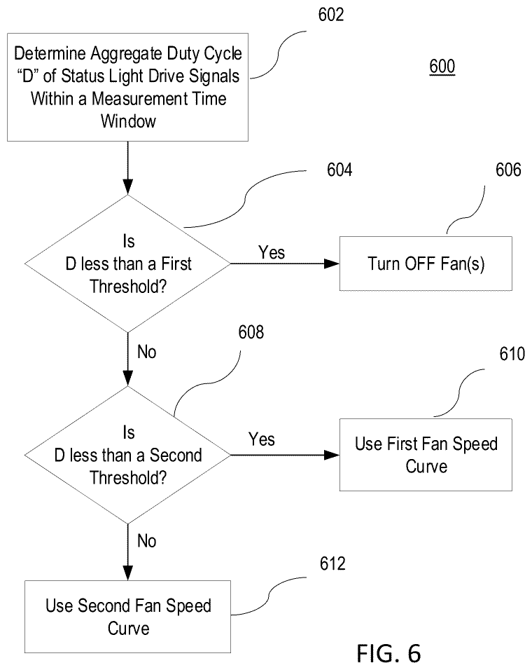

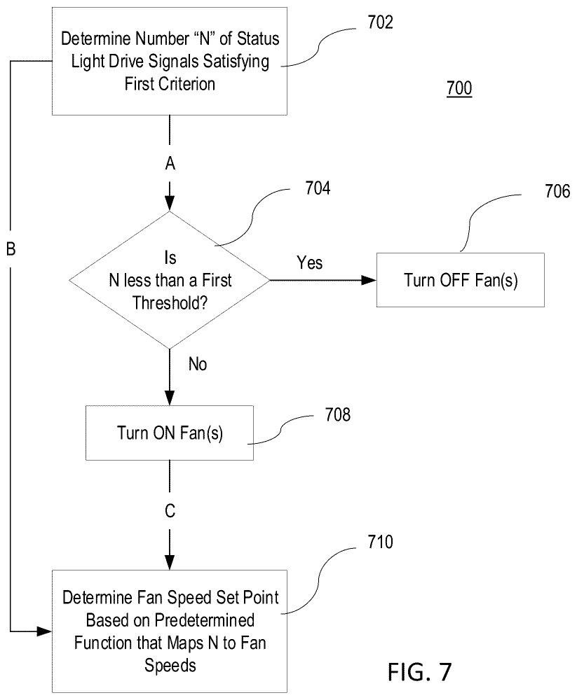

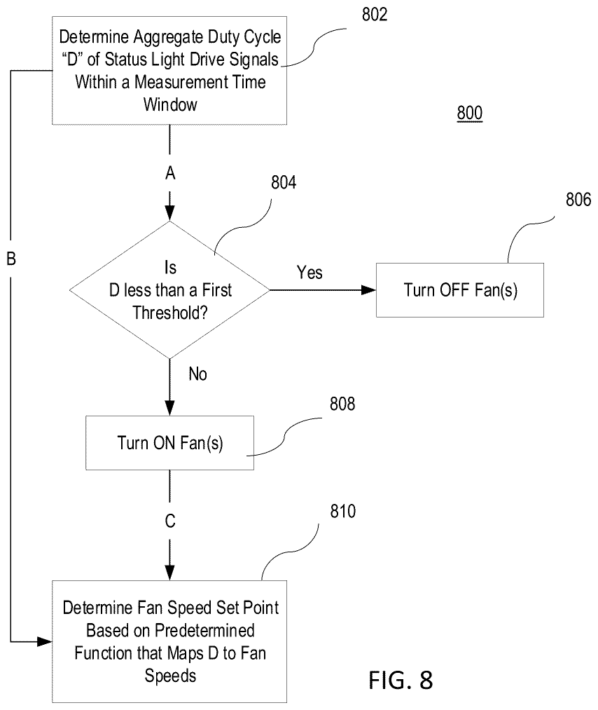

In some examples, operation 154 comprises setting the fan speed set point based directly on the fan control signals 146, while in other examples, operation 154 comprises setting the fans speed set point based indirectly on the fan control signals 146. For example, FIGS. 7 and 8, described in greater detail below, illustrate some examples in which the fan speed set point is based directly on the fan control signals 146, whereas FIGS. 5 and 6, described in greater detail below, illustrate some examples in which the fan speed set point is based indirectly on the fan control signals 146. In some examples in which the fan speed set point is based indirectly on the fan control signals 146, predefined fan control schemes (e.g., a fan speed curve) may be used by the fan control logic 151 to directly control the fan speed set point based on some predefined parameter (e.g., temperature), and the fan control signals 146 may be used to determine which one of the fan control schemes is used, thus indirectly controlling (i.e., influencing) the fan speed set point.

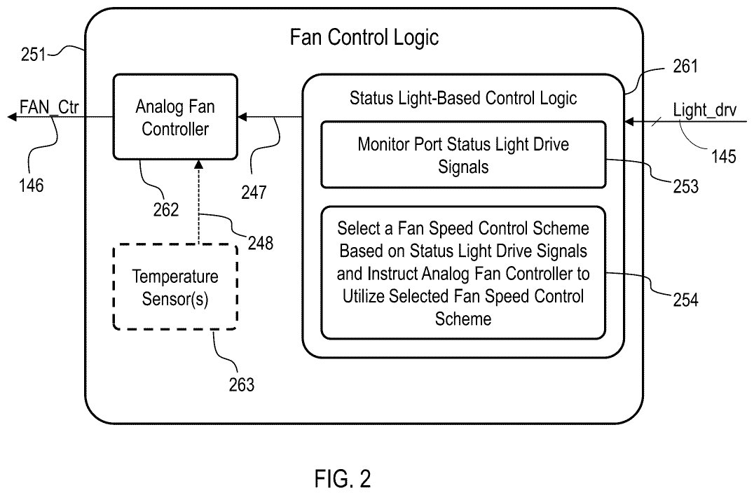

In some implementations, the fan control logic 151 may comprise multiple distinct controllers that work together to control the fan(s) 142, such as a first controller that generates the fan control signals 146 and a second controller that monitors the status light drive signals 145 and instructs the first controller based thereon. In other words, in these examples, some of the functionality of the operation 154 is performed by one controller (i.e., the generation of the fan control signals 146) while other functionality of the operation 154 is performed by a distinct controller (which may also perform the operation 153). For example, as illustrated in FIG. 2, a fan control logic 251 (which is an example configuration of the fan control logic 151) may include a status light-based control logic 261 that works in combination with an analog fan controller 262 to issue the fan control signals 146. The analog fan controller 262 may generate the fan control signals 146 utilizing any of multiple predetermined fan speed control schemes, such as temperature based fan speed curves or any other desired fan control scheme. The status light-based control logic 261 is configured to execute an operation 253 to monitor the port status light drive signals 145 and an operation 254 to select a fan speed control scheme (e.g., a fan curve) based on the drive signals 145 and to issue instructions 247 to the analog fan controller 262 to utilize the selected fan speed control scheme. The fan controller 262 may then issue the fan control signals 146 to set the airflows provided by the one or more fans 142 based on the selected fan speed control scheme, for example, based on one or more preloaded fan speed curves, as would be understood by those of ordinary skill in the art. In some examples, the fan control logic 151 comprises, or is communicably coupled with, one or more temperature sensors 363 that sense temperatures within networking device 110 and provide signal 248 indicative of the temperature to the analog fan controller 262, with the analog fan controller 262 generating the fan control signals 146 based at least in part on the signal 248. For example, as noted above, the analog fan controller 262 may utilize a fan speed curve that maps the sensed temperature to a fan speed set point. The selection of the fan control scheme in operation 254, together with the generation of the fan control signals 146 by the analog fan controller 262 according to the selected fan control scheme, comprise one example implementation of the operation 154 described above. In some examples, the analog fan controller 262 may be a commercially available fan microcontroller as would be familiar to one of ordinary skill in the art, whereas status light-based control logic 261 may comprise a separate and distinct controller such as another microcontroller, a general purpose processor executing instructions, or other control circuitry.

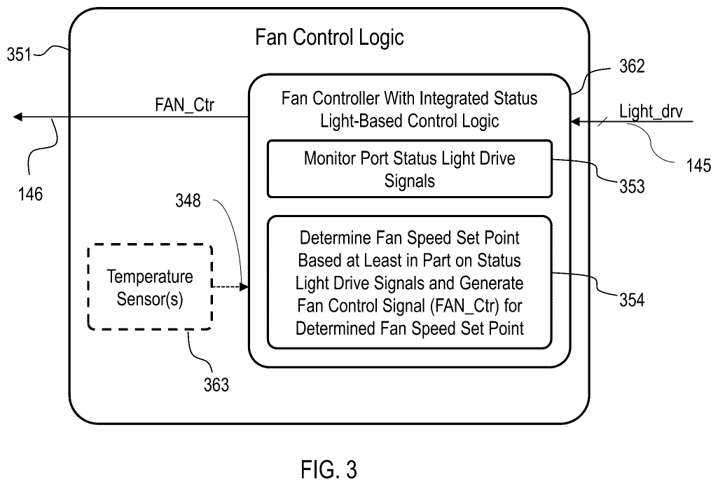

In some other implementations, instead of splitting aspects of the operation 154 between two controllers, the functionalities of operations 153 and 154 are integrated into the same controller. For example, as illustrated in FIG. 3, a fan control logic 351, which is another example configuration of the fan control logic 151, may include a fan controller 362 with an integrated status light-based control logic that may directly issue the fan control signals 146. For example, the fan controller 362 is configured to execute an operation 353 to monitor the port status light drive signals 145 and an operation 354 to determine a fan speed set point based at least in part on the drive signals 145 and issue the fan control signals 146 to set the airflows provided by the one or more fans 142 based at least in part on the determined fan speed set point. In some examples, the fan controller 362 may receive a signal 348 indicative of a sensed temperature from one or more temperature sensors 363 and utilize a fan speed curve to determine the fan speed setpoint based on the signal 348. In such examples, the fan controller 362 may determine which fan speed curve to utilize, out of multiple preprogramed fan speed curves, based on the status light drive signals 145. In other examples, the fan controller 362 may be configured, for example, to determine a fan speed set point based on a predetermined functional relationship between the drive signals and the fan speed. For example, the number of drive signals that have a particular value (e.g., an ON value, or an ON value for a particular color, or a particular duty cycle or frequency) may be related to corresponding fan speed set points, thus defining a functional relationship between drive signals and set points. This functional relationship may be stored in a table of discrete values accessible to the fan control logic 351, or in some cases may be stored as an explicit formula that is evaluated by the fan control logic 351, as would be understood by those of ordinary skill in the art. The operation 354 comprises another example implementation of the operation 154 described above.

In examples that utilize distinct controllers to perform aspects of operations 153 and 154, it is possible in some examples to utilize a commercially available fan controller as the first controller that generates the fan control signals 146. This can allow for the status light-based functionalities of operations 153 and 154 to be relatively easily added to existing or new designs that incorporate a conventional fan controller without requiring the modification or redesign of that fan controller-instead, separate control logic that handles the status light-based functionalities can be added alongside the existing analog fan controller. This can be, in some circumstances, less expensive and/or less complicated than designing a new fan controller that can perform both functionalities. On the other hand, in examples that utilize a single controller to perform operations 153 and 154, the number of discrete components that are needed may be reduced, which can also be beneficial in some circumstances. Moreover, in some cases, operations 153 and 154 may be implemented as instructions that can be programmed into a fan microcontroller, which can allow for existing devices to be upgraded by reprogramming a fan microcontroller thereof to perform the operations 153 and 154.

As further illustrated in each of FIGS. 2 and 3, in some examples, the fan control logic 251, 351 may also include one or more temperature sensors 263, 363, which may provide additional input to the fan controllers 262, 362 to assist in issuing the fan control signals 146 to adjust the provided airflow. In this manner, the fan control logic 251, 351 may be further configured to execute an operation to monitor signals 248, 348 from the temperature sensors 263, 363 and to control the airflows provided by the one or more fans 142 based at least in part on the signals 248, 348 from the one or more temperature sensors 263, 363 (e.g., based on both the port status LED drive signals 145 and the temperature sensor signals 248, 348). Cooling control of a networking device, such as a PSE, utilizing temperature sensors, is well known in the art and would be familiar to those of ordinary skill in the art, thus the temperature sensors 263, 363, and associated control logic, are not describe in greater detail herein.

As noted above, port status light control logic 152 controls the port status lights 141. Specifically, the port status light control logic 152 generates status light drive signals 145, which are communicably connected to the ports 141 by one or more communications paths (e.g., wires) and control light emission of the port status lights 141. In some examples, the port status light control logic 152 may monitor the ports 140 and then generate the drive signals 145 configured to cause each of the status lights 141 to illuminate (or refrain from illuminating) in a manner indicative of a current status or activity of the corresponding ports 140. For example, the statuses or activities of a given port that may be indicated by the port status lights 141 may include any one or more of: a connection state of the port to another device; whether PoE power is being supplied via the port to another device; whether data is currently being transmitted via the port; a magnitude or intensity of data being communicated via the port; whether the port is in a high-power and/or high-speed state or a low-power and/or low-speed state; whether the port and/or connected device is experiencing a fault; or any other state of the port. Moreover, the port status lights 141 may be driven to indicate any of the aforementioned statuses by one or more of: emitting light to indicate one status and refraining from emitting light to indicate the absence or opposite of the status; emitting light of a particular color to indicate a particular status (wherein there are multiple possible colors to choose from to selectively indicate one of multiple statuses); emitting light at a particular intensity to indicate a particular status (wherein there are multiple possible intensities to choose from to selectively indicate one of multiple statuses); emitting light in a steady state to indicate one status or in a flashing manner to indicate another status; flashing at a particular frequency or duty cycle to indicate a particular status (wherein there are multiple possible frequencies or duty cycles to choose from to selectively indicate one of multiple statuses); and/or emitting light in a predetermined pattern of flashes to indicate a status. For example, in some implementations the status light control signals 145 are configured to turn on a port status light 141 when a connection is established to the corresponding port 140, to turn on the port status light 141 when PoE power is supplied to the corresponding port 140, to flash the port status light 141 based on an amount of data transmitted/received via the corresponding port 140, and/or to change a color of the port status light 141 based on one or more activity indicators (e.g., emit light in one color when a data connection is made and emit light in another color when PoE data is being supplied). The status light drive signals 145 may be digital or analog electrical signals that can change between at least two values to cause the port status lights 141 to illuminate in the desired manner. For example, in some implementations each status light drive signals 145 may comprise a high voltage value that causes the port status light 141 to turn ON (emit light) and a low voltage value that causes the port status light 141 to turn OFF (refrain from emitting light). In some examples, each port status light 141 receives just one corresponding status light drive signal 145, while in other examples each port status light 141 may receive multiple corresponding status light drive signals 145 (e.g., one per color that the port status light 141 is capable of emitting). In FIG. 1, a single communication path for drive signals 145 is illustrated per port status light 141 for ease of illustration, but in practice there may be multiple such communication paths per port status light 141. Port status lights of a networking device and the control logic that monitors the ports and drives the port status lights are familiar to those of ordinary skill in the art, and thus the port status light control logic 152 of the control circuitry 150 is not described in greater detail herein.

In some additional examples, the control circuitry 150 may be configured to control other operations of the networking device 110 in addition to the operations 153 and 154, such as controlling operations of the switching hardware 120, operations of the power supply 130, security/authentication operations, and/or other operations of the networking device 110. Such other operations of control circuitry are familiar to those of ordinary skill in the art, and thus are not described in detail herein.

Furthermore, in addition to the operations described above, in some examples, the control circuitry 150 of the networking device 110 may be configured to perform any of the operations described below in relation to the methods 500, 600, 700, and/or 800 of FIGS. 5-8.

Turning now to FIGS. 5-8, example methods 500, 600, 700, and 800 will be described. The methods 500, 600, 700, and 800 may be performed, for example, by the networking device 110 described above. In particular, in some examples, the methods 500, 600, 700, and/or 800 may be performed by the control circuitry 150 of the networking device 110 employing the fan control logic 151, 251, 351 discussed above. In some examples, as also discussed above, the control circuitry 150 comprises a computer readable storage medium 160 (see FIG. 4) storing instructions corresponding to the operations of methods 500, 600, 700, and/or 800 i.e., instructions configured to cause the networking device 110 to perform the methods 500, 600, 700, and/or 800 when executed by a processor of the control circuitry 150. In some examples, the control circuitry 150 comprises a dedicated hardware configured to perform the methods 500, 600, 700, and/or 800. In some examples, the control circuitry 150 is configured to perform the methods 500, 600, 700, and/or 800 by a combination of a processor executing instructions and dedicated hardware.

With reference to FIGS. 5 and 6, in each of the methods 500 and 600 the fans are controlled based not only on status light drive signals 145 but also based on one or more pre-loaded fan curves, which may be used by the fan control logic 151 (e.g., the fan control logic 251) to control the airflows provided by the one or more fans 142 to cool the networking device 110, as described in greater detail below. The method 500 comprises operations of blocks 502, 504, 506, 508, 510, and 512, and the method 600 comprises operations of blocks 602, 604, 606, 608, 610, and 612. Blocks 502 and 602 are example implementations of (i.e., may be performed as part of) operations 153, 253, or 353 described above, while blocks 504 to 512 and 604 to 612 are example implementations of (i.e., may be performed as part of) operations 154, 254, and 354 described above.

As illustrated in FIG. 5, in some example methods, when monitoring the port status light drive signals 145 as part of operation 153, at block 502, the control circuitry 150 of the networking device 110 may determine a total number N of the drive signals 145 that satisfy a first criterion (e.g., count each drive signal 145 that satisfies the first criterion to determine a total number N of the drive signals 145). The first criterion may be satisfied for a particular drive signal 145 if the drive signal 145 is associated with a predetermined status or port activity indicator. The drive signal 145 is associated with a predetermined status if the drive signal is configured to cause the port status light 141 that receives the signal 145 to illuminate (or refrain from illuminating) in a manner that indicates the predetermined status. For example, if the predetermined status is an established connection between one of the ports 140 and one of the remote devices, and if this status is indicated by turning ON the corresponding port status light 141, then the drive signals 145 that satisfy the first criterion may include all those drive signals 145 having ON-values configured to turn on the corresponding status lights 141. As another example, if the predetermined status is delivery of PoE power via one of the ports 140, and if this status is indicated by causing the corresponding port status light 141 to emit a particular color, then the drive signals 145 that satisfy the first criterion may include all those drive signals 145 having values configured to cause the corresponding status lights 141 to emit the particular color. In this manner, in some examples, the first criterion may comprise at least one of: 1) the drive signal 145 having an ON value that is configured to turn on one of the port status lights 141, 2) the drive signal 145 having an ON value configured to cause one of the port status lights 141 to emit a predetermined color, 3) the drive signal 145 having a voltage equal to a predetermined voltage, 4) the drive signal 145 having a voltage equal to or greater than the predetermined voltage, 5) the drive signal 145 having a predetermined duty cycle or frequency or a duty cycle or frequency that is equal to or greater than a predetermined value, and/or 6) the drive signal 145 being indicative of a predetermined port status.

At block 504, the control circuitry 150 may then compare the total number N of the drive signals 145 that satisfy the first criterion to a first threshold to determine whether the threshold has been met, and based on this information, the control circuitry 150 (e.g., via the fan control logic 151) may control the airflows provided by the one or more fans 142. If the total number of drive signals N, for example, is less than the first threshold then the process may continue to block 506 and the control circuitry 150 may deactivate some or all of the one or more fans 142 (i.e., turn the one or more fans 142 to an off state, or keep the fans off if they are already off). In some examples, all of the fans 142 are deactivated. In other examples, just some of the fans 142 are deactivated, for example, fans that flow air through a portion of the device that does not have a temperature sensor (e.g., a PSU) may be turned off, whereas other fans associated with a portion of the device that does have a temperature sensor may remain on and controlled by any desired fan control scheme. Deactivating the fans 142 may be beneficial because it may reduce the amount of noise generated and power consumed, and doing so may be possible when N is less than the threshold because N being low may indicate that a low amount of heat is being generated in the device. For example, if the signals 145 that satisfy the criteria are those that indicate PoE power is being drawn, then a low number N indicates that few devices are drawing PoE power, and thus heat generated by a PSU may be expected to be low. In contrast, if N is high then the amount of heat being generated may be expected to be higher, and thus the fans may need to be activated, as described further below.

Returning to block 504, if the total number of drive signals N is greater than or equal to the first threshold, then the process may continue to blocks 508 to 512. In block 508, the control circuitry 150 may compare the total number of drive signals N to a second threshold. The second threshold may be greater than the first threshold. For example, if the total number of drive signals N is less than the second threshold, the process continues to block 510 and the control circuitry 150 may activate the one or more fans 142 by setting the respective speeds of the fans 142 based on the first fan speed curve, while, if the total number of drive signals N is greater than or equal to the second threshold the process continues to block 512 and the control circuitry 150 may activate the one or more fans 142 by setting the respective speeds of the fans 142 based on a second fan speed curve.

Those of ordinary skill in the art would understand that the method 500 illustrated and described with reference to FIG. 5 is exemplary only, and that the contemplated methods may have various combinations of steps, all of which are not illustrated for simplicity, and that some illustrated steps could be omitted in some cases. For example, in some examples, blocks 504 and 506 may be omitted. As another example, in some examples blocks 508 and 512 are omitted and the process may proceed from block 504 directly to block 510 if N is equal to or greater than the first threshold in block 504. As another example, in some examples any number of additional fan speed curves beyond the first and second fan speed curves may be utilized by adding additional blocks analogous to block 508 wherein N may be compared to additional thresholds. In other words, the method 500 may select one of any number of fan speed curves based on the number N of status light drive signals 145 that satisfy the first criterion, with each fan speed curve being associated with a different number or range of numbers N. Furthermore, it would be understood, that based on various factors such as, for example, the number of monitored ports 140, locations of the fans 142, and/or the presence of established cooling zones within the networking device 110, there could also be more than one determined total number N of drive signals 145 and more than one criterion, such that a first group of one or more fans 142 is controlled based on a first total number N₁ and/or a first criterion and a second group of one or more fans 142 is controlled based on a second total number N₂ and/or a second criterion. In this manner, in controlling the airflows provided by the one or more fans 142, the control circuitry 150 may select to implement more than one fan speed curve at a time.

Moreover, the contemplated methods may monitor the drive signals 145 for driving the port status lights 141 based on any number of port activity indicators and are not limited to monitoring the signals 145 based on a total number N of the drive signals 145 as discussed above. As illustrated in FIG. 6, for example, in some additional example methods, when monitoring the port status light drive signals 145 (e.g., the port status LED drive signals 145), at block 602, the control circuitry 150 of the networking device 110 may instead determine an aggregate duty cycle D of the drive signals 145 within a given measurement time window. As used herein, the “duty cycle” of a port status light drive signal 145 refers to a measurement of the amount of time that the respective signal 145 has an on value (a value that causes the corresponding light 141 to turn on) (e.g., as related to a flashing rate of the associated port status light 141) during a given reference time period. Thus, for example, if a drive signal 145 has an on value half of the time during a reference time window, then the duty cycle for that signal 145 during that window is 50%. The aggregate duty cycle of the drive signals 145 refers to an aggregation of the individual duty cycles of the drive signals 145, such as a sum, average, weighted average, or other statistical aggregation of these values. As understood in the art, this ratio of time is generally indicative of the power delivered at or utilized by the port, with signals having longer duty cycles indicating more power, which potentially may require an increase in fan airflow to the networking device 110. In other words, in such an example, the duty cycle of each drive signal 145 may be indicative of a load associated with one of the ports 140. For example, in some implementations the port status light 141 flash to indicate communications activity through the corresponding port 140, and greater activity through the port 140 may result in a greater amount of flashing of the port status light 141 and thus a higher duty cycle (proportion of on-time) of the drive signal 145. Thus, in such examples, the aggregate duty cycle may be correlated with a total amount of communication activity for the networking device.

At block 604, the control circuitry 150 may then compare the aggregate duty cycle D to a first threshold to determine whether the first threshold has been met, and based on this information, control (e.g., via the fan control logic 151) the airflows provided by the one or more fans 142.

Similar to the above method 500, if the aggregate duty cycle D is less than the first threshold, then the process continues to block 606 and the control circuitry 150 may deactivate the one or more fans 142 (i.e., turn the one or more fans 142 off). While, if the aggregate duty cycle D is greater than or equal to the first threshold, the control circuitry 150 may activate the one or more fans 142, select a fan speed curve, and set respective speeds of the fans 142 based on the selected fan speed curve. Specifically, if in block 604 D is greater than or equal to the first threshold, the process continues to block 608, and the control circuitry 150 compares the aggregate duty cycle D to a second threshold, which is greater than the first threshold. For example, if the aggregate duty cycle D is less than the second threshold, then the process continues to block 610 and the control circuitry 150 may activate the one or more fans 142 and set the respective speeds of the fans 142 based on the first fan speed curve, while, if the aggregate duty cycle D is greater than or equal to the second threshold, the process continues to block 612 and the control circuitry 150 may activate the one or more fans 142 by setting the respective speeds of the fans 142 based on a second fan speed curve.

As noted above with respect to method 500, the method 600 illustrated and described with reference to FIG. 6 is exemplary only, and the contemplated methods may have various combinations of steps, all of which are not illustrated for simplicity, and that some illustrated steps could be omitted in some cases.

In the methods 500 and 600 described above, the first and second fan speed curves are different than one another. For example, in some implementations the second fan speed curve may be more aggressive than the first fan speed curve, by which it is meant that the second fan speed curve may have a higher maximum speed, have a steeper slope, and/or reach a maximum speed sooner than the first fan speed curve. In some examples, all of the fans 142 are controlled according to the selected fan speed curve, whereas in other examples a subset of the fans 142 are controlled according to the selected fan speed curve, such as the fan(s) 142 that provide cooling to a PSU. Using a more aggressive fan speed curve when N or D is larger may be beneficial because a larger N or D is generally correlated with a larger amount of heat being generated, and thus a more aggressive fan curve may be needed to ensure adequate heat dissipation. In particular, in some examples the fan(s) 142 being controlled cool the PSU and the temperature inputs that are used in the fan speed curve to determine the speed set point may come from a temperature sensor at the control circuitry 150 that does not fully reflect the temperature PSU, and therefore if the fans were controlled solely based on the temperature sensor and fan curve, the PSU may be inadequately cooled in situations where the PSU is heavily loaded while the control circuitry 150 or switching hardware 120 is lightly loaded. However, in examples in which N or D reflects the amount of power being provided by the PSU, a larger N or D may indicate that the PSU needs additional cooling. Thus, by using a more aggressive fan curve when N or D is large, the PSU can be sufficiently cooled even if control circuitry 150 or switching hardware 120 is lightly loaded. In other examples, N or D may reflect a load of some other component of the device or of the device as a whole, and thus a larger N or D may be correlated with a need for increased cooling.

Although not specifically illustrated in a flow chart, in some further example methods, when monitoring the port status light drive signals 145, the control circuitry 150 of the networking device 110 may instead determine a color change of one or more of the port status lights 141 (e.g., the port status LEDs 141) and based on the color change data control (e.g., via the fan control logic 151) the airflows provided by the one or more fans 142, in a similar manner as described above with regard to methods 500 and 600.

Those of ordinary skill in the art would understand that the above-described thresholds in the methods 500 and 600 may be determined and set based on a given application and depending on, for example, the particular system components and cooling requirements of a given networking device 110. Furthermore, as fan speed curves and their implementation within a fan control logic (e.g., for cooling a networking device) are familiar to those of ordinary skill in the art, they are not described in detail herein.

As discussed above, the contemplated methods of cooling a network device, such as the network device 110, may have various combinations of steps, which include both monitoring the port status LED drive signals 145 and setting a speed of one or more of the fans 142 based at least in part on the drive signals 145. In the methods 500 and 600, the setting of the speed of the fans 142 is based in part on the status light control signals (which are used to select a fan speed curve) and in part on a sensed temperature. However, in other examples methods the speed of one or more of the fans 142 may be set more directly based on the status light control signals without necessarily relying on temperature sensors and fan curves. For example, in FIGS. 7 and 8, methods 700 and 800 are illustrated that may run to generally switch the fans 142 on and off (see, e.g., sequence A) and/or adjust a speed of the fans 142 (see, e.g., sequence B and C) based directly on the status light control signals (i.e., based on how many of the status light control signals satisfy a given condition).

The methods 700 and 800 may be generally similar to one another except that in method 700 the total number N of the drive signals 145 that satisfy a first criterion is used as a deciding factor, whereas in the method 800 the aggregate duty cycle D of the drive signals 145 is used as a deciding factor. Thus, similar to block 506 of the methods 500 discussed above, in some examples, in the method 700, at block 702, the control circuitry 150 may determine a total number N of the drive signals 145 that satisfy a first criterion (e.g., count each drive signal 145 that satisfies the first criterion to determine a total number N of the drive signals 145). Moreover, similar to block 602 of the method 600 described above, in the method 800, at block 802, the control circuitry 150 may instead determine an aggregate duty cycle D of the drive signals 145 within a given measurement time window. Based on this respective information (e.g., the determined total number N of the drive signals 145 or the determined aggregate duty cycle D of the drive signals 145), the methods 700 and 800 may then run one or more of a sequence of steps A, B, and/or C.

In sequence A, similar to the above methods 500 and 600 at blocks 704, 804 the control circuitry 150 may respectively compare the total number N (block 704) or the aggregate duty cycle D (block 706) to a first threshold to determine whether the first threshold has been met. If the total number N or the aggregate duty cycle D is less than the first threshold, then the methods 700 and 800 continue to blocks 706 and 806, respectively, and the control circuitry 150 may deactivate the one or more fans 142 (i.e., if the fans 145 are already running (are in an on state), turn the fans 142 to an off state). Alternatively, if the fans 142 are already in the off state, the control circuitry 150 may maintain the fans in the off state. While, if the total number N or the aggregate duty cycle D is greater than or equal to the first threshold, the methods 700 and 800 continue to at blocks 708 and 808, respectively, and the control circuitry 150 may activate the one or more fans 142 (i.e., if the fans 145 are in the off state, turn the fans 142 to the on state). Alternatively, if the fans 142 are already in the on state, the control circuitry 150 may maintain the fans in the on state.

In some examples, sequence A may embody the full extent of the methods 700, 800, while in some other examples, the methods 700, 800 may continue from sequence A into sequence C, in which a speed of the one or more fans 142 is also set. In sequence C, as illustrated in FIGS. 7 and 8, at blocks 710, 810 the control circuitry 150 may determine a fan speed set point for the one or more fans 142 based on a predetermined functional relationship between the drive signals 145 and the fan speed (e.g., a predetermined function that maps the total number N or the aggregate duty cycle D to the fan speed). For example, as described above with regard to the fan control logic 351, a fan controller 362 with integrated status light-based control logic may be used to determine the fan speed set point by consulting a table or evaluating a formula that maps N and/or D to corresponding fan speed set points.

As also illustrated in FIGS. 7 and 8, in still some additional examples, the methods 700, 800 may skip sequences A and C altogether and proceed directly from blocks 702 or 802 to blocks 710, 810 via sequence B. In such examples, the one or more fans 142 may continuously run (i.e., always be in the on state) and have their fan speed set point be adjusted based directly on the determined total number N or the aggregate duty cycle D. It would be understood that the illustrated methods 700 and 800, and included sequences A, B, and C, are exemplary only and may comprise any number of additional sequences and/or steps, which are not illustrated for simplicity. Furthermore, a networking device 110 employing such methods may utilize more than one of sequences A, B, and C and any combination of sequences A, B, and/or C.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A networking device, comprising:
ports connectable via respective communications links to remote devices;
port status lights, each of the ports being associated with at least one of the port status lights configured to indicate a status of the port;
one or more fans, each of the one or more fans being configured to provide an airflow through the networking device; and
control circuitry configured to, in a state of at least one remote device being connected to at least one of the ports:
monitor drive signals for driving the port status lights; and
control the airflows provided by the one or more fans based at least in part on the drive signals for driving the port status lights.

2. The device of claim 1, wherein the ports are configured to provide power-over-ethernet (PoE) and the remote devices comprise PoE powered devices (PD), such that the ports are connectable via the respective communications links to the PDs to supply power to and exchange communications with the PDs.

3. The device of claim 1, wherein the port status lights comprise light-emitting diodes (LEDs).

4. The device of claim 1, wherein the control circuitry is further configured to:
monitor signals from one or more temperature sensors; and
control the airflows provided by the one or more fans based at least in part on the signals for the one or more temperature sensors.

5. The device of claim 1, wherein the control circuitry is configured to, as part of monitoring the drive signals for driving the port status lights:
determine a total number of the drive signals that satisfy a first criterion; and
compare the total number of the drive signals that satisfy the first criterion to a first threshold.

6. The device of claim 5, wherein the first criterion comprises at least one of:
the drive signal having an ON value configured to turn on one of the port status lights;
the drive signal having an ON value configured to cause one of the port status lights to emit a predetermined color;
the drive signal having a voltage equal to a predetermined voltage;
the drive signal having a voltage equal to or greater than the predetermined voltage;
the drive signal having a duty cycle or frequency equal to or greater than a predetermined value; and/or
the drive signal being indicative of a predetermined status.

7. The device of claim 5, wherein each drive signal that satisfied the first criterion is indicative of an established connection between one of the ports and one of the remote devices and/or a transmission of data between one of the ports and one of the remote devices.

8. The device of claim 5, wherein the control circuitry is configured to, in controlling the airflows provided by the one or more fans based at least in part on the drive signals:
activate the one or more fans if the total number of the drive signals that satisfy the first criterion is greater than or equal to the first threshold; and
deactivate the one or more fans if the total number of the drive signals that satisfy the first criterion is less than the first threshold.

9. The device of claim 8, wherein activating the one or more fans comprises the control circuitry setting respective speeds of the one or more fans based on a first fan speed curve.

10. The device of claim 9, wherein the control circuitry is configured to:
in monitoring the drive signals for driving the port status lights, if the total number of the drive signals that satisfy the first criterion is greater than or equal to the first threshold, compare the total number of the drive signals to a second threshold; and
in controlling the one or more fans based at least in part on the drive signals:
set a speed of the one or more fans based on a first fan speed curve if the total number of the drive signals is less than the second threshold and equal to or greater than the first threshold; and
set the speed of the one or more fans based on a second fan speed curve if the total number of the drive signals is greater than or equal to the second threshold.

11. The device of claim 5, wherein the control circuitry is configured to, in monitoring the drive signals for driving the port status lights, if the total number of the drive signals that satisfy the first criterion is greater than or equal to the first threshold, compare the total number of the drive signals to a second threshold.

12. The device of claim 5, wherein the control circuitry is configured to, in controlling the airflows provided by the one or more fans based at least in part on the drive signals:
select a first fan speed curve for controlling rotational speeds of the one or more fans if the total number of the drive signals that satisfy the first criterion is less than the first threshold; and
select a second fan curve for controlling rotational speeds of the one or more fans if the total number of the drive signals that satisfy the first criterion is equal to or greater than the first threshold.

13. The device of claim 1, wherein the control circuitry is configured to, in monitoring the drive signals for driving the port status lights:
determine an aggregate duty cycle of the drive signals within a predetermined measurement time window; and
compare the aggregate duty cycle to a first threshold.

14. The device of claim 13, wherein a duty cycle of each drive signal is indicative of a load associated with one of the ports.

15. The device of claim 13, wherein the control circuitry is configured to, in controlling the one or more fans based at least in part on the drive signals:
activate the one or more fans if the aggregate duty cycle of the drive signals is greater than or equal to the first threshold; and
deactivate the one or more fans if the aggregate duty cycle of the drive signals is less than the first threshold.

16. The device of claim 15, wherein activating the one or more fans comprises the control circuitry setting a speed of the one or more fans based on a first fan speed curve.

17. A method of cooling a network device, the method comprising:
monitoring drive signals for driving port status lights associated with one or more communication ports of the network device, the port status lights being configured to indicate a status of the one or more communication ports; and
setting a speed of one or more fans of the network device based at least in part on the drive signals for driving the port status lights.

18. The method of claim 17, wherein monitoring the drive signals for driving the port status lights comprises:
determining a total number of the drive signals that satisfy a first criterion;
determining an aggregate duty cycle of the drive signals within a predetermined measurement time window; and/or
determining a color change of one or more of the port status lights.

19. The method of claim 17, wherein setting a speed of the one or more fans of the network device based at least in part on the drive signals comprises:
activating the one or more fans based on the drive signals;
deactivating the one or more fans based on the drive signals;
selecting a fan speed curve from among multiple fan speed curves based on the drive signals, the selected fan speed curve being used to determine a fan speed set point; and/or
determining a fan speed set point based on a predetermined functional relationship between the drive signals and the fan speed.

20. A non-transitory computer readable medium storing instructions executable by a processor and configured to, when executed, cause the processor to:
monitor drive signals for driving port status lights associated with one or more communication ports, the port status lights being configured to indicate a status of the one or more communication ports; and
control one or more fans based at least in part on the drive signals for driving the port status lights.
